(19) United States
(12) Patent Application Publication
(10) Pub. No.: US 2013/0022218 A1
(43) Pub. Date: Jan. 24, 2013

(54) SOUND CONTROL APPARATUS, PROGRAM, AND CONTROL METHOD

(71) Applicants: Yusuke Miyazawa, Tokyo (JP); Yasuyuki Koga, Kanagawa (JP); Tatsushi Nashida, Kanagawa (JP)

(72) Inventors: Yusuke Miyazawa, Tokyo (JP); Yasuyuki Koga, Kanagawa (JP); Tatsushi Nashida, Kanagawa (JP)

(21) Appl. No.: 13/517,778

(22) Filed: Jun. 14, 2012

(30) Foreign Application Priority Data
Jun. 24, 2011 (JP) 2011-141037

(51) Int. Cl. H03G 3/00

(52) U.S. Cl. 381/104

(57) ABSTRACT

A sound control apparatus includes a display unit and a controller. The display unit is configured to display an object on a screen. The controller is configured to control a volume of information on the object based on one of a position and area of the object on the screen.

### BACKGROUND

The present disclosure relates to a technique used in, for example, a sound control apparatus that controls sound from headphones, earphones, a speaker, and the like.

From the past, a technique for controlling sound signals such that sound is heard from a certain direction has been known.

Japanese Patent Application Laid-open No. 2008-92193 discloses a technique in which a plurality of virtual sound sources for music are arranged in a virtual sound source space, and sound signals from headphones are controlled such that music is heard from a direction of the plurality of virtual sound sources. For example, assuming that a user wearing headphones faces right from a state where he/she is facing front, music that the user has heard from the front direction when facing front is heard from the left-hand direction, and music that the user has heard from the right-hand direction when facing front is heard from the front direction.

### SUMMARY

There is a need for a technique with which information on an object displayed on a screen can be heard in a volume corresponding to a position or area of the object on the screen.

According to an embodiment of the present disclosure, there is provided a sound control apparatus including a display unit and a controller.

The display unit is configured to display an object on a screen.

The controller is configured to control a volume of information on the object based on one of a position and area of the object on the screen.

For example, assuming that a jacket of a song, an advertisement, or the like (object) is displayed on the screen, a content of the song, advertisement, or the like is heard in a volume corresponding to a position or area of the jacket of the song, advertisement, or the like that is displayed on the screen.

In the sound control apparatus, the controller may control a sound signal of a sound output unit such that the information on the object is heard from a direction corresponding to the position of the object on the screen.

In the sound control apparatus, a content of the song, advertisement, or the like (information on object) is heard from the direction corresponding to the position of the jacket of the song, advertisement, or the like (object) displayed on the screen in a volume corresponding to the position or area of the jacket of the song, advertisement, or the like.

In the sound control apparatus, the controller may control the volume of the information on the object based on a distance between a center position of the screen and a center position of the object.

In the sound control apparatus, the controller may control the volume of the information on the object such that the volume becomes larger as the distance between the center position of the screen and the center position of the object becomes smaller.

With this structure, the volume of the information on the object becomes larger as the object approaches the center position of the screen.

In the sound control apparatus, the controller may control the volume of the information on the object such that the volume becomes larger as the area of the object on the screen increases.

With this structure, the volume of the information on the object becomes larger as the area of the object on the screen increases.

In the sound control apparatus, the controller may control the volume of the information on the object based on both the position and area of the object on the screen.

The sound control apparatus may further include an input unit. In this case, the controller may, judge a selection operation of the object via the input unit and change the volume of the information on the selected object according to the selection operation of the object.

In the sound control apparatus, the controller may change the volume of the information on the selected object such that the volume of the information on the selected object becomes larger.

The sound control apparatus may further include an image pickup unit configured to pick up an image of a real object that actually exists in space. In this case, the controller may cause the real object photographed by the image pickup unit to be displayed as the object on the screen and control a volume of information on the real object based on one of a position and area of the real object on the screen.

In the sound control apparatus, when the user photographs the jacket of the song, advertisement, or the like (real object) that actually exists in space, the photographed jacket of the song, advertisement, or the like is displayed on the screen. Then, the content of the song, advertisement, or the like (information on real object) is heard in a volume corresponding to the position or area of the jacket of the song, advertisement, or the like on the screen.

In the sound control apparatus, the controller may change, when one of the position and area of the real object photographed by the image pickup unit on the screen is changed, the volume of the information on the real object according to the change of one of the position and area of the real object on the screen.

In the sound control apparatus, when the user changes the position or area of the real object on the screen by changing the position of the image pickup unit with respect to the real object, for example, the volume of the information on the real object is changed according to the change of the position or area of the real object on the screen.

In the sound control apparatus, the controller may cause a virtual object to be displayed as the object on the screen and control a volume of information on the virtual object based on one of a position and area of the virtual object on the screen.

In the sound control apparatus, the jacket of the song, advertisement, or the like is displayed as a virtual object on the screen. Then, the content of the song, advertisement, or the like (information on virtual object) is heard in a volume corresponding to the position or area of the jacket of the song, advertisement, or the like on the screen.

In the sound control apparatus, the controller may change one of the position and area of the virtual object on the screen and change the volume of the information on the virtual object according to the change of one of the position and area of the virtual object on the screen.

The sound control apparatus may further include a sensor configured to detect a movement of the sound control apparatus. In this case, the controller may change one of the position and area of the virtual object on the screen according to the movement of the sound control apparatus detected by the sensor.

In the sound control apparatus, when the user tilts the sound control apparatus, the position or area of the virtual object on the screen changes according to the movement of the sound control apparatus. When the position or area of the virtual object on the screen changes, the volume of the information on the virtual object is changed according to the change of the position or area of the virtual object on the screen.

According to an embodiment of the present disclosure, there is provided a program that causes a sound control apparatus to execute the steps of: displaying an object on a screen; and controlling a volume of information on the object based on one of a position and area of the object on the screen.

According to an embodiment of the present disclosure, there is provided a control method including displaying an object on a screen.

A volume of information on the object is controlled based on one of a position and area of the object on the screen.

As described above, according to the embodiments of the present disclosure, the technique with which information on an object displayed on a screen can be heard in a volume corresponding to a position or area of the object on the screen can be provided.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a diagram showing a sound control apparatus (cellular phone) and headphones according to an embodiment of the present disclosure;

FIG. 2 is a block diagram showing an electrical structure of the sound control apparatus;

FIG. 3 is a flowchart showing processing of the cellular phone (controller) according to the embodiment of the present disclosure;

FIG. 4 is a diagram showing a state where a user photographs a jacket of a song such as a record jacket and a CD jacket (real object) with an image pickup unit;

FIG. 5 is a diagram showing an example of a distance between a center position of a screen and a center position of the song jacket displayed on the screen;

FIG. 6 is a diagram showing an example of positions of sound sources of the song jackets and volumes of the songs at a time the song jackets are displayed on the screen in the positional relationship shown in FIG. 5;

FIG. 7 is a diagram showing a state where the user touches a certain song jacket;

FIG. 8 is a diagram showing a state where a plurality of songs included in a musical album are arranged and displayed at a position where the musical album is displayed;

FIG. 9 is a diagram showing an example of a case where a plurality of song jackets having different sizes are displayed on the screen; and

FIG. 10 is a flowchart showing processing of the cellular phone (controller) according to another embodiment of the present disclosure.

### DETAILED DESCRIPTION OF EMBODIMENTS

Hereinafter, embodiments of the present disclosure will be described with reference to the drawings.

[Overall Structure of Sound Control Apparatus and Structures of Components]

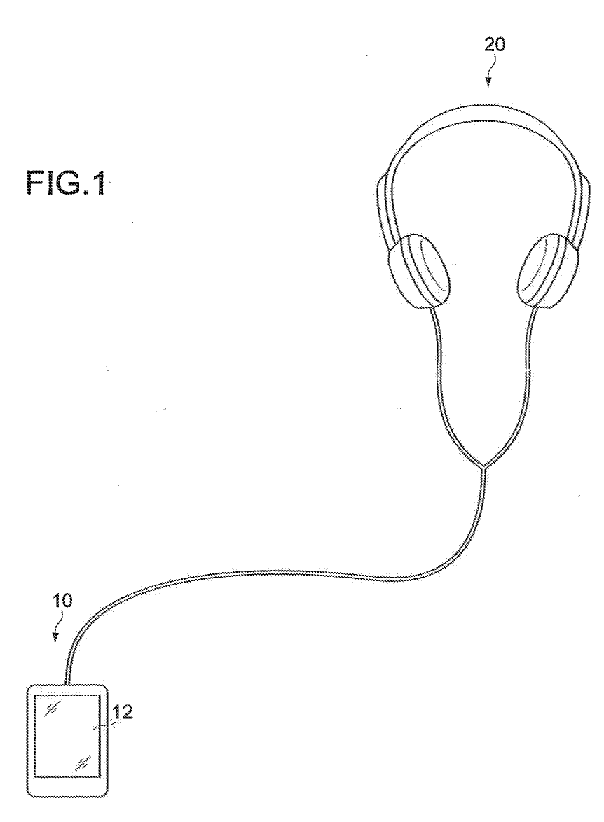

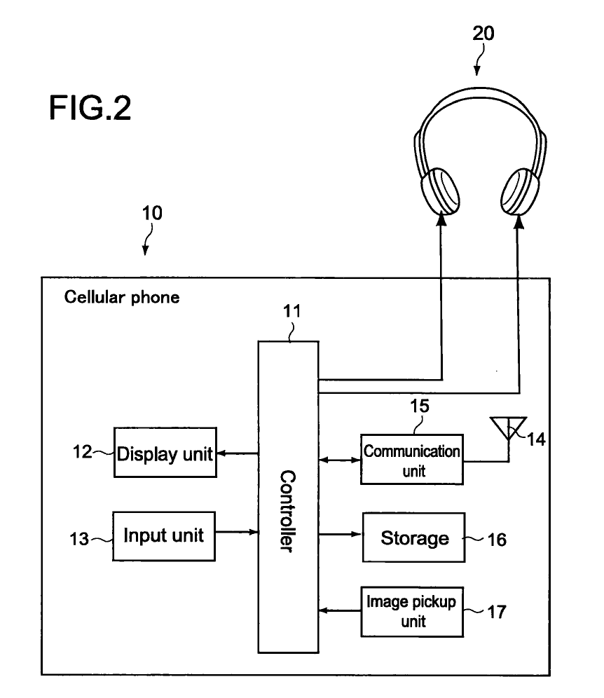

FIG. 1 is a diagram showing a sound control apparatus 10 and headphones 20 according to an embodiment of the present disclosure. FIG. 2 is a block diagram showing an electrical structure of the sound control apparatus 10. In the first embodiment, a cellular phone 10 will be taken as an example of the sound control apparatus 10.

The cellular phone 10 includes a controller 11, a display unit 12, an input unit 13, an antenna 14, a communication unit 15, a storage 16, and an image pickup unit 17. The cellular phone 10 also includes a communication speaker, a communication microphone, and the like (not shown).

The storage 16 includes a volatile memory (e.g., RAM (Random Access Memory)) and a nonvolatile memory (e.g., ROM (Read Only Memory)). The volatile memory is used as a working area of the controller 11 and temporarily stores programs and data such as music data and video data that are used for processing of the controller 11. The nonvolatile memory fixedly stores various programs and data such as music data and video data requisite for processing of the controller 11. The programs stored in the nonvolatile memory may be read out from a portable recording medium such as an optical disc and a semiconductor memory.

The controller 11 is constituted of a CPU (Central Processing Unit) or the like. The controller 11 executes various operations based on the programs stored in the storage 16.

The image pickup unit 17 is constituted of an image pickup device such as a CCD (Charge Coupled Device) sensor and a CMOS (Complementary Metal Oxide Semiconductor) sensor. Signals output from the image pickup unit 17 are A/D-converted and input to the controller 11.

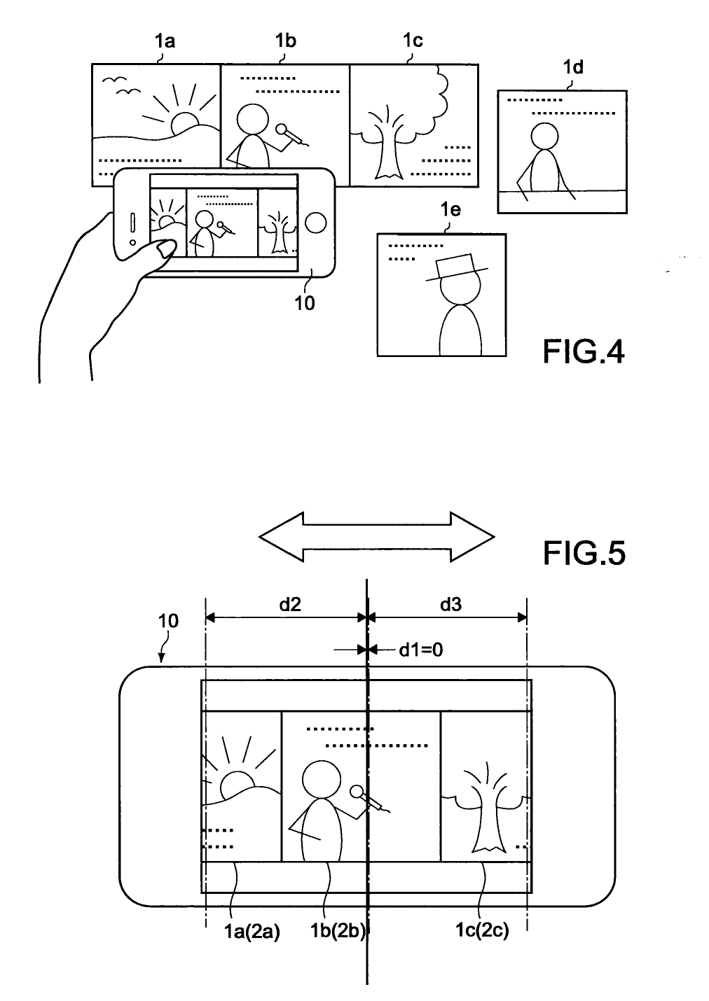

The image pickup unit 17 picks up an image of a real object 1 (AR marker) that actually exists in space (see FIG. 4). As the real object 1, there is a song jacket 1 (including single jacket and album jacket) such as a record jacket and a CD (Compact Disc) jacket. Also as the real object 1, there are, for example, a moving image jacket such as a video tape jacket and a DVD jacket and an advertisement such as a product advertisement and a movie advertisement poster.

The display unit 12 is constituted of, for example, a liquid crystal display or an EL (Electro-Luminescence) display. Under control of the controller 11, the display unit 12 displays an image taken by the image pickup unit 17 on a screen.

The input unit 13 includes a touch sensor that detects a user operation with a finger, a stylus pen, or the like with respect to the display unit 12 and an input button provided on the cellular phone 10.

The communication unit 15 executes processing of converting a frequency of radio waves transmitted and received by the antenna 14, modulation processing, demodulation processing, and the like. The antenna 14 transmits and receives communication radio waves and packet communication radio waves for an email and web data.

The communication unit 15 is communicable with an information management server (not shown). The information management server stores the real object 1 (AR marker) photographed by the image pickup unit 17 and information on the real object 1 in association with each other.

The information on the real object 1 is, for example, sound information of a song included in a record or a CD in a case where the real object 1 (AR marker) is a song jacket 1 such as a record jacket and a CD jacket. In a case where the real object 1 is a moving image jacket such as a video tape jacket and a DVD jacket, for example, the information on the real object 1 is sound information of the moving image. Further, in a case where the real object 1 is an advertisement such as a product advertisement and a movie advertisement poster, for example, the information on the real object 1 is sound information indicating a content of the product or movie.

In response to a request from the sound control apparatus 10, the information management server executes, for example, processing of transmitting the information on the real object 1 to the sound control apparatus 10.

The headphones 20 are connected with the cellular phone 10 in a wired or wireless manner.

[Explanation on Operation]

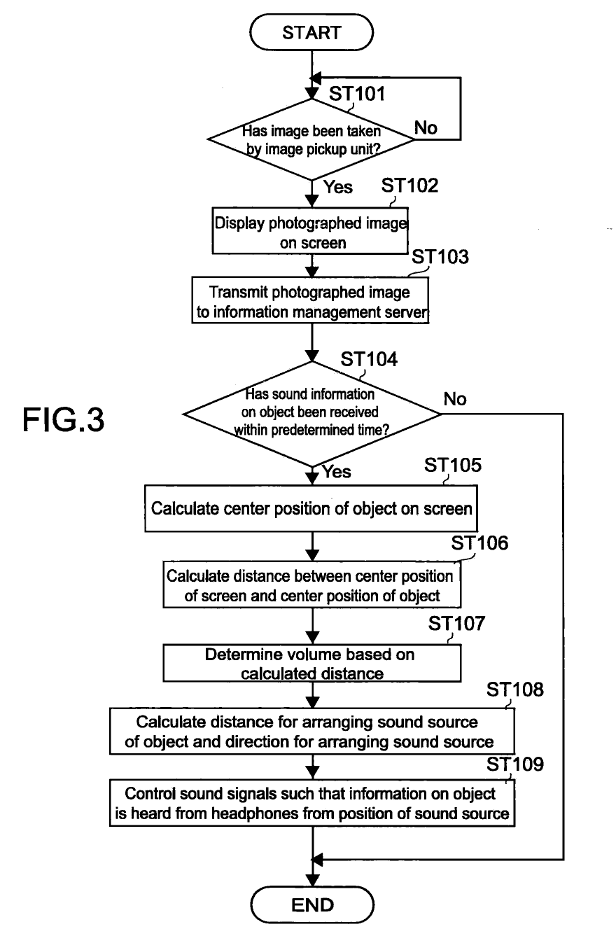

Next, processing by the controller 11 of the cellular phone 10 according to the embodiment of the present disclosure will be described. FIG. 3 is a flowchart showing the processing of the cellular phone 10 (controller 11) according to this embodiment. FIGS. 4 to 6 are complementary diagrams for explaining the processing shown in FIG. 3.

First, a user wears the headphones 20. Then, the user holds the cellular phone 10 in the hand and activates the image pickup unit 17. Next, the user photographs the real object 1 that actually exists in space with the image pickup unit 17.

The real object 1 to be photographed is, as described above, a song jacket 1 such as a record jacket and a CD jacket, a moving image jacket such as a video tape jacket and a DVD jacket, and an advertisement such as a product advertisement and a movie advertisement poster.

FIG. 4 shows a state where the user photographs the song jacket 1 (real object) such as a record jacket and a CD jacket with the image pickup unit 17. For example, the user places the song jacket 1 (1a to 1e) that he/she owns on a table and photographs the song jacket 1 with the image pickup unit 17. Alternatively, the user may photograph the song jacket 1 displayed in a record/CD store or a record/CD rental shop with the image pickup unit 17.

Referring to FIG. 3, the controller 11 of the cellular phone 10 judges whether an image has been taken by the image pickup unit 17 (Step 101). When an image has been taken by the image pickup unit 17 (YES in Step 101), the controller 11 causes the photographed image to be displayed on the screen of the display unit 12 (Step 102). Also in this case, the controller 11 transmits information on the photographed image to the information management server via the communication unit 15 (Step 103).

Upon receiving the image information, the information management server judges whether there is a real object 1 (AR marker) associated with sound information in the image based on the image information. Whether there is a real object 1 associated with sound information in the image is judged by, for example, an image matching method.

When there is a real object 1 associated with sound information in the image, the information management server transmits information on the real object 1 to the cellular phone 10. For example, when the real object 1 is the song jacket 1, the information management server transmits sound information of a song included in the record or CD to the cellular phone 10. Further, when the real object 1 is a moving image jacket such as a DVD jacket or an advertisement such as a product advertisement and a movie advertisement poster, sound information of the moving image or sound information indicating a content of the product or movie advertisement is transmitted to the cellular phone 10.

When there are a plurality of real objects 1 associated with sound information in the image, the information management server transmits the sound information for each of the plurality of real objects 1 to the cellular phone 10. There may be a case where the user photographs a plurality of types of real objects 1, and an image including the plurality of types of real objects 1 is transmitted to the information management server. For example, an image including two types of real objects 1 including the song jacket 1 and the moving image jacket 2 may be transmitted to the information management server. In this case, the information management server transmits sound information corresponding to one type of real object 1 to the cellular phone 10.

Further, there may be a case where a plurality of sound information items are associated with one real object 1. In this case, the information management server transmits the plurality of sound information items associated with the one real object 1 to the cellular phone 10. For example, when the real object 1 is an album jacket for songs, the information management server transmits sound information of a plurality of songs included in the album to the cellular phone 10.

In the example shown in FIG. 4, since the plurality of song jackets 1 are photographed by the user, sound information for each of the plurality of song jackets 1 is transmitted from the information management server to the cellular phone 10.

Referring to FIG. 3, upon transmitting the information on the photographed image to the information management server, the controller 11 of the cellular phone 10 judges whether information on the real object 1 has been received within a predetermined time since the transmission of the image information (Step 104). The time is, for example, about 5 to 10 seconds. When the predetermined time has elapsed without receiving the information on the real object 1 (NO in Step 104), that is, when there is no real object 1 associated with sound information in the photographed image, the controller 11 of the cellular phone 10 ends the processing.

On the other hand, when the information on the real object 1 has been received within the predetermined time (YES in Step 104), the controller 11 calculates a center position of the real object 1 on the screen (Step 105). When there are a plurality of real objects 1 on the screen, the controller 11 calculates the center position on the screen for each of the plurality of real objects 1.

Next, the controller 11 calculates a distance between the center position of the screen and the center position of the real object 1 (Step 106). When there are a plurality of real objects 1 on the screen, the distance is calculated for each of the plurality of real objects 1.

FIG. 5 shows an example of the distance between the center position of the screen and the center position of the song jacket 1 displayed on the screen. In the example shown in FIG. 5, a distance d1 between the center position of the screen and a center position of a song jacket 1b displayed at the center of the screen is 0. Also in the example shown in FIG. 5, a distance d2 between the center position of the screen and a center position of a song jacket 1a displayed on the left-hand side of the screen and a distance d3 between the center position of the screen and a center position of a song jacket 1c displayed on the right-hand side of the screen are the same.

Referring to FIG. 3, upon calculating the distance between the center position of the screen and the center position of the song jacket 1, the controller 11 determines a volume of information on the real object 1 based on the calculated distance (Step 107). In this case, the controller 11 sets the volume of the information on the real object 1 such that it becomes larger as the distance between the center position of the screen and the center position of the song jacket 1 becomes smaller. When there are a plurality of real objects 1 on the screen, the controller 11 determines the volume of information for each of the plurality of real objects 1.

Next, the controller 11 calculates a distance between a position at which a sound source for the real object 1 is to be arranged and the headphones 20 (user) and a direction for arranging the sound source for the real object 1 (Step 108). The direction for arranging the real object 1 is calculated based on the center position of the real object 1 on the screen. When there are a plurality of real objects 1 on the screen, the controller 11 calculates the distance of the sound source and the direction for arranging the sound source for each of the plurality of real objects 1.

Next, the controller 11 controls sound signals such that the information on the real object 1 is heard from the headphones 20 from the position of the sound source for the real object 1 (Step 109).

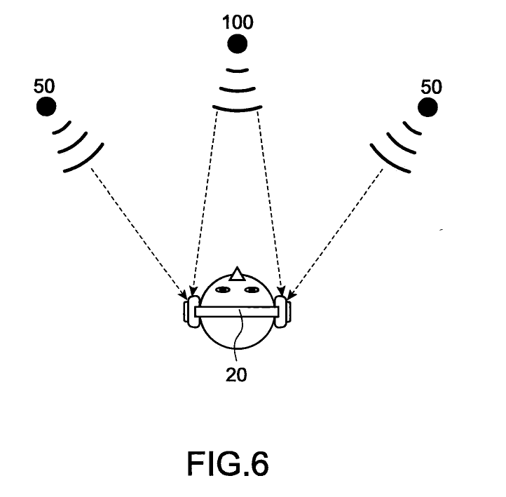

FIG. 6 is a diagram showing an example of the positions of the sound sources for the song jackets 1 and volumes of the songs. FIG. 6 shows an example of the positions of the sound sources for the song jackets 1 and the volumes of the songs at a time the song jackets 1 are displayed on the screen in the positional relationship shown in FIG. 5.

Referring to FIGS. 5 and 6, the sound source for the song jacket 1b displayed at the center of the screen is arranged in front of the user (headphones 20), the sound source for the song jacket 1a displayed on the left-hand side of the screen is arranged in front of the user (headphones 20) on the left, and the sound source for the song jacket 1c displayed on the right-hand side of the screen is arranged in front of the user (headphones 20) on the right. In addition, the volume is controlled such that the song of the song jacket 1b that is close to the center position of the screen and displayed at the center of the screen is heard in a volume 100. The volume is also controlled such that the songs of the song jackets 1a and 1c that are distant from the center position of the screen and displayed at the right- and left-hand side of the screen are heard in a volume 50.

Referring to FIGS. 4 and 5, assuming that the user holds a portable terminal and moves it leftwardly, for example, the plurality of song jackets 1 displayed on the screen move rightwardly on the screen. At this time, according to the rightward movement of the song jackets 1 on the screen, the positions of the sound sources for the song jackets 1 change so that the positions shift rightwardly. Also at this time, the volumes of the songs of the song jackets 1 change according to the rightward movement of the song jackets 1 on the screen.

Specifically, the controller 11 changes, when the position of the real object 1 photographed by the image pickup unit 17 is changed on the screen, the volume of the information on the real object 1 according to the change of the position of the real object 1 on the screen. In the example in this case, the song jacket 1b displayed at the center of the screen and the song jacket 1c displayed on the right-hand side of the screen in FIG. 5 move rightwardly and move away from the center position of the screen. Therefore, the volumes of the songs of the song jackets 1b and 1c displayed at the center and on the right-hand side of the screen become smaller. On the other hand, the song jacket 1a displayed on the left-hand side of the screen in FIG. 5 moves rightwardly to come closer to the center position of the screen, and thus the volume of the song of the song jacket 1a becomes larger.

For example, when the real object 1 is an album jacket for songs, sound information of a plurality of songs associated with the album jacket is transmitted from the information management server. In this case, the songs included in the album are reproduced in order or at random.

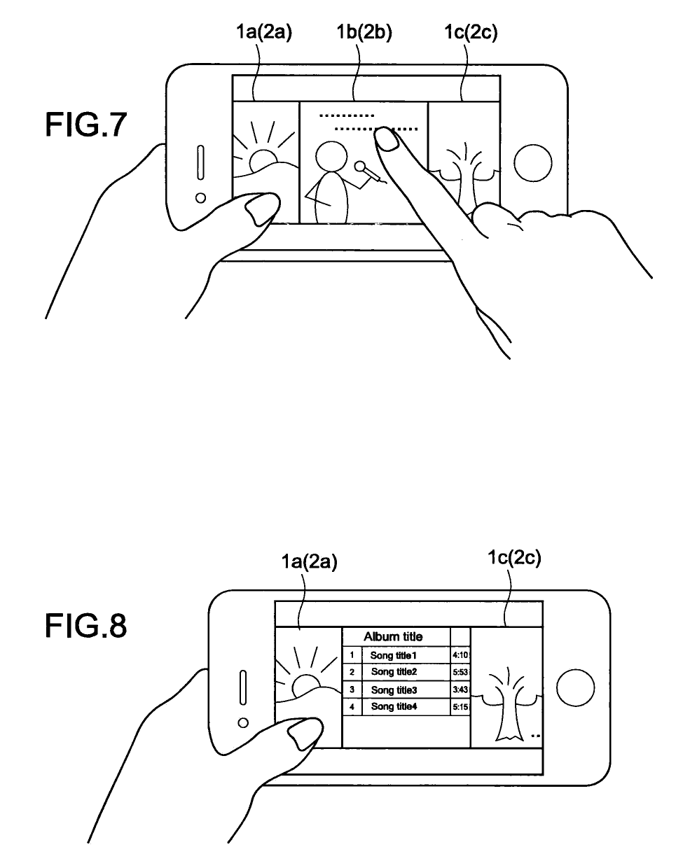

FIG. 7 is a diagram showing a state where the user selects and touches a certain song jacket 1 (album jacket). FIG. 8 is a diagram showing a state of the screen after the user touches the song jacket (album jacket).

As shown in FIGS. 7 and 8, when the user selects and touches a certain song jacket 1 (album jacket), a plurality of songs included in the album are displayed at the position where the song jacket 1 has been displayed. By selecting and touching an arbitrary song from the plurality of songs, the user can select the song included in the album.

As shown in FIG. 7, when the user selects a certain song jacket 1 (real object 1), the volume of the song of the selected song jacket 1 may be changed. In this case, the controller judges a selection operation of the song jacket 1 via the input unit and changes the volume of the song of the selected song jacket 1 according to the selection operation of the song jacket 1. At this time, the controller typically changes the volume of the selected song jacket 1 such that it becomes larger. The controller may start reproducing only the song of the selected song jacket 1.

By the processing shown in FIG. 3, the user can enjoy a song by placing the song jacket 1 that he/she owns on a table and photographing it with the image pickup unit 17. Further, by photographing the song jacket 1 displayed at a record/CD store or a record/CD rental shop with the image pickup unit 17, the user can listen to a sample of a song. It should be noted that a song provided when photographing the song jacket 1 at a record/CD store or a record/CD rental shop is not an entire song and is merely sample music. The user can select a record, CD, and the like by listening to the samples.

Further, since the song of the song jacket 1 displayed on the screen is heard in a volume corresponding to the position of the song jacket 1 on the screen from a direction corresponding to the position of the song jacket 1 on the screen, the user can intuitively recognize the direction of the song.

In the descriptions above, the case where the real object 1 that is photographed by the image pickup unit 17 and displayed on the screen is the song jacket 1 has been described based on the specific example. However, also when the real object 1 displayed on the screen is a moving image jacket, an advertisement, or the like, the user can experience a similar entertainment.

For example, in a case where the user places a moving image jacket such as a video tape jacket and a DVD jacket that he/she owns on a table and photographs the moving image jacket with the image pickup unit 17 so that it is displayed on the screen, the user can enjoy sound information of the moving image. Also by photographing a moving image jacket displayed at a video/DVD store or a video/DVD rental shop with the image pickup unit 17, the user can listen to introduction information on a content of the moving image, and the like.

On the other hand, in a case where the user finds an advertisement such as a product advertisement and a movie advertisement poster while walking on a street and photographs it so that it is displayed on the screen, the user can listen to a content of the product advertisement or a content of the movie advertisement.

### Modified Example of First Embodiment

The descriptions above have been given on the case where the volume of information on the real object 1 is controlled based on the position of the real object 1 displayed on the screen. On the other hand, the volume of information on the real object 1 may be controlled based on an area of the real object 1 displayed on the screen. In this case, the controller 11 executes, in place of Steps 106 and 107 shown in FIG. 3, processing of calculating an area of the real object 1 displayed on the screen and processing of determining a volume based on the calculated area. In this case, the controller 11 typically controls the volume such that it becomes larger as the area of the real object 1 on the screen increases.

For example, a case where a plurality of song jackets 1 having different sizes are photographed or a plurality of song jackets 1 whose distances from the image pickup unit 17 (cellular phone 10) differ will be discussed. In this case, the plurality of song jackets 1 having different sizes are displayed on the screen.

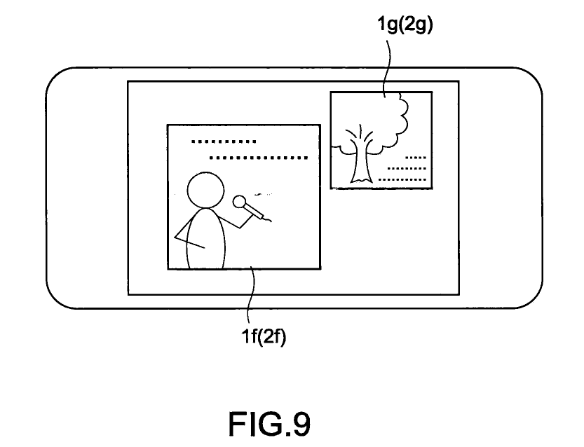

FIG. 9 is a diagram showing an example of the case where the plurality of song jackets 1 having different sizes are displayed on the screen. In the example shown in FIG. 9, an area of a song jacket 1f displayed on the left-hand side of the screen is larger than that of a song jacket 1g displayed on the right-hand side of the screen. Therefore, a volume of a song of the song jacket 1f displayed on the left-hand side of the screen becomes larger than a volume of a song of the song jacket 1g displayed on the right-hand side of the screen.

Further, also when the song jackets 1 having the same size are photographed as shown in FIGS. 4 and 5, for example, since the song jackets 1 cannot be fully displayed on the screen, the areas of the song jackets 1 may differ on the screen. In the example shown in FIG. 5, the area of the song jacket 1a displayed on the left-hand side of the screen and the area of the song jacket 1c displayed on the right-hand side of the screen are about half the area of the song jacket 1b displayed at the center of the screen.

Referring to FIG. 6, in this case, the volume is controlled such that the song of the song jacket 1b whose area is largest on the screen and that is displayed at the center of the screen is heard in a volume 100. In addition, the volumes are also controlled such that the songs of the song jackets 1a and 1c whose areas on the screen are relatively small and that are displayed on the left- and right-hand side of the screen are heard in a volume 50.

On the other hand, a case where the user moves the cellular phone 10 close to or away from the song jacket 1 while photographing the song jacket 1 will be discussed. In this case, the size of the song jacket 1 on the screen changes. Similarly, as the song jacket 1 moves into the screen or moves out of the screen when the user moves the cellular phone 10 up, down, and to the sides while photographing the song jacket 1, the size of the song jacket 1 changes on the screen. In this case, when the area of the song jacket 1 on the screen is changed, the controller 11 changes the volume of the song according to the change of the area of the song jacket 1 on the screen.

In the modified example of the first embodiment, the descriptions on the specific example have been given on the case where the photographed real object 1 is the song jacket 1. However, the processing is the same even when the photographed real object 1 is a moving image jacket or an advertisement.

The descriptions above have been given on the case where the volume of the information on the real object 1 is controlled based on either the position or area of the real object 1 displayed on the screen. However, the present disclosure is not limited thereto, and the controller 11 may control the volume of the information on the real object 1 based on both the position and area of the real object 1 on the screen.

### Second Embodiment

Next, a second embodiment of the present disclosure will be described. In descriptions below, descriptions on parts having the same structures and functions as those of the first embodiment above will be omitted or simplified.

The cellular phone 10 (sound control apparatus 10) according to the second embodiment is different from that of the first embodiment in that a motion sensor (not shown) that detects a movement of the cellular phone 10 is added. Examples of the motion sensor include an acceleration sensor, an angular velocity sensor, a velocity sensor, and an angle sensor. Other points are the same as the first embodiment, and thus descriptions thereof will be omitted.

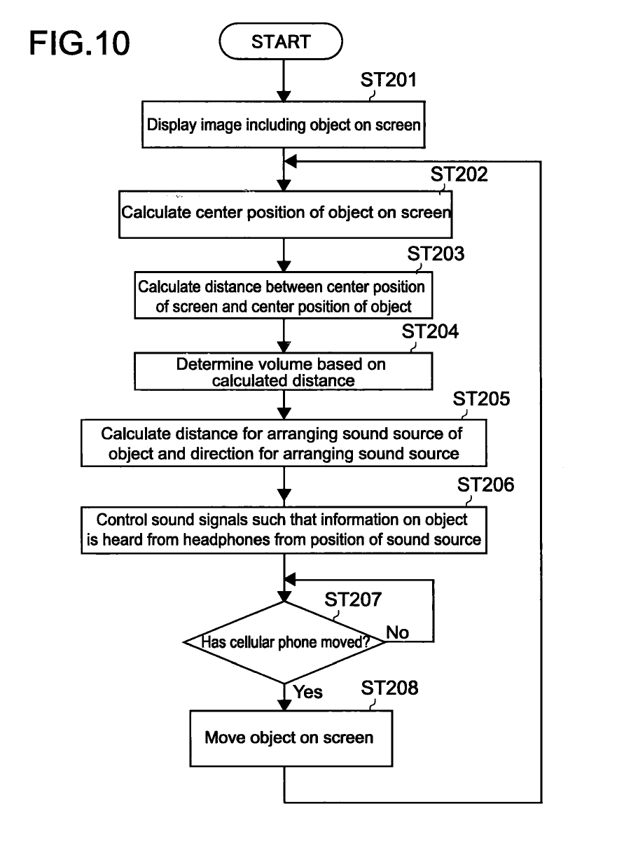

FIG. 10 is a flowchart showing processing of the cellular phone 10 according to the second embodiment.

First, the user wears the headphones 20 and holds the cellular phone 10 in hand.

The controller 11 of the cellular phone 10 first reads out an image including a virtual object 2 from the storage 16 and displays it on the screen (Step 201). As the virtual object 2 displayed on the screen, there are a song jacket 1 such as a record jacket and a CD jacket, a moving image jacket such as a video tape jacket and a DVD jacket, and an advertisement such as a product advertisement and a movie advertisement poster.

Specifically, the virtual object 2 is typically the same as the real object 1 described above except that, instead of being photographed by the image pickup unit 17 and displayed on the screen, the virtual object 2 is displayed on the screen as an image stored in the storage 16.

In Step 201, song jackets 2a to 2c as shown in FIG. 5 are displayed on the screen as the virtual objects 2. As the virtual objects 2, the song jackets 2 of the same artist or genre may be displayed as one group.

Upon displaying an image including the virtual object 2 on the screen, the controller 11 calculates a center position of the virtual object 2 on the screen (Step 202). When there are a plurality of virtual objects 2 on the screen, the controller 11 calculates a center position of each of the plurality of virtual objects 2 on the screen.

Next, the controller 11 calculates a distance between the center position of the screen and the center position of the virtual object 2 (Step 203). When there are a plurality of virtual objects 2 on the screen, the distance is calculated for each of the plurality of virtual objects 2.

Upon calculating the distance between the center position of the screen and the center position of the virtual object 2, the controller 11 determines a volume of information on the virtual object 2 based on the calculated distance (Step 204). In this case, the controller 11 controls the volume of the information on the virtual object 2 such that it becomes larger as the distance between the center position of the screen and the center position of the virtual object 2 becomes smaller. When there are a plurality of virtual objects 2 on the screen, the controller 11 determines the volume of sound information for each of the plurality of virtual objects 2.

Next, the controller 11 calculates a distance between a position at which a sound source for the virtual object 2 is to be arranged and the headphones 20 (user) and a direction for arranging the sound source for the virtual object 2 (Step 205). When there are a plurality of virtual objects 2 on the screen, the controller 11 calculates the distance of the sound source and the direction for arranging the sound source for each of the plurality of virtual objects 2.

Next, the controller 11 controls sound signals such that the information on the virtual object 2 is heard from the headphones 20 from the position of the sound source for the virtual object 2 (Step 206). The information on the virtual object 2 is typically the same as the information on the real object 1 described above. The information on the virtual object 2 may be stored in the storage 16 of the cellular phone 10 in advance or may be obtained from the information management server via the communication unit 15.

Subsequently, the controller 11 judges whether the cellular phone 10 has moved based on an output from the motion sensor (Step 207). When judged that the cellular phone 10 has moved (YES in Step 207), the controller 11 moves the virtual object 2 on the screen according to the movement of the cellular phone 10.

For example, assuming that the user moves the cellular phone 10 that he/she is holding in the longitudinal and lateral directions, the controller 11 moves the virtual object 2 displayed on the screen in the opposite direction from the cellular phone 10. For example, when the user moves the cellular phone 10 in the left-hand direction, the virtual object 2 is moved in the right-hand direction on the screen.

Upon moving the virtual object 2 on the screen, the controller 11 returns to Step 202 and calculates the center position of the object on the screen. Then, the processing of Steps 203 to 206 are executed. As a result, when the user moves the portable terminal and the position of the virtual object 2 is thus changed on the screen, the position of the sound source for the virtual object 2 and the volume of the information on the virtual object 2 are changed according to the change of the position of the virtual object 2 on the screen.

By the processing as described above, the information on the virtual object 2 displayed on the screen is heard in a volume corresponding to the position of the virtual object 2 on the screen from a direction corresponding to the position of the virtual object 2 on the screen. As a result, the user can intuitively recognize the direction of the virtual object 2 and the like.

Referring to FIG. 7, when the user selects a certain song jacket 2 (virtual object 2), a volume of a song of the selected song jacket may be changed.

### Modified Example of Second Embodiment

The descriptions above have been given on the case where the volume of information on the virtual object 2 is controlled based on a position of the virtual object 2. On the other hand, the volume of information on the virtual object 2 may be controlled based on an area of the virtual object 2 on the screen. In this case, the controller 11 executes, in place of Steps 203 and 204 shown in FIG. 10, processing of calculating an area of the virtual object 2 displayed on the screen and processing of determining a volume based on the calculated area. In this case, the controller 11 typically controls the volume such that it becomes larger as the area of the virtual object 2 on the screen increases.

For example, when the user moves the cellular phone 10 that he/she is holding in the longitudinal and lateral directions, the virtual object 2 displayed on the screen is moved in the opposite direction from the cellular phone 10. Therefore, in this case, as the virtual object 2 moves into the screen or moves out of the screen, the size of the virtual object 2 changes on the screen. In this case, when the area of the virtual object 2 is changed on the screen, the controller 11 changes the volume of the information on the virtual object 2 according to the change of the area of the virtual object 2 on the screen.

Further, when the cellular phone 10 is moved, the controller 11 may actively change the area of the virtual object 2 on the screen according to the movement of the cellular phone 10. For example, the area of the virtual object 2 on the screen may also be changed when the user brings the hand holding the cellular phone 10 closer to him/herself or moves it away. In this case, when the area of the virtual object 2 is changed on the screen, the controller 11 may change the volume of the information on the virtual object 2 according to the change of the area of the virtual object 2 on the screen.

The controller 11 may control the volume of the information on the virtual object 2 based on both the position and area of the virtual object 2 on the screen.

### Various Modified Examples

In the descriptions above, the headphones 20 have been taken as an example of the sound output unit that outputs sound. However, earphones (sound output unit) may be used instead of the headphones 20. Alternatively, instead of the headphones 20, a speaker provided in the cellular phone 10 itself or a speaker provided separate from the cellular phone 10 may be used.

In the descriptions above, the cellular phone 10 has been taken as an example of the sound control apparatus 10, though not limited thereto. The cellular phone 10 may be a portable music player, a PDA (Personal Digital Assistance), a tablet PC (Personal Computer), or the like.

The present disclosure may also take the following structures.

(1) A sound control apparatus, including:

a display unit configured to display an object on a screen; and

a controller configured to control a volume of information on the object based on one of a position and area of the object on the screen.

(2) The sound control apparatus according to (1),

in which the controller controls a sound signal of a sound output unit such that the information on the object is heard from a direction corresponding to the position of the object on the screen.

(3) The sound control apparatus according to (1) or (2),

in which the controller controls the volume of the information on the object based on a distance between a center position of the screen and a center position of the object.

(4) The sound control apparatus according to (3),

in which the controller controls the volume of the information on the object such that the volume becomes larger as the distance between the center position of the screen and the center position of the object becomes smaller.

(5) The sound control apparatus according to (1) or (2),

in which the controller controls the volume of the information on the object such that the volume becomes larger as the area of the object on the screen increases.

(6) The sound control apparatus according to (1) or (2),

in which the controller controls the volume of the information on the object based on both the position and area of the object on the screen.

(7) The sound control apparatus according to (1) or (2), further including

an input unit,

in which the controller judges a selection operation of the object via the input unit and changes the volume of the information on the selected object according to the selection operation of the object.

(8) The sound control apparatus according to (7),

in which the controller changes the volume of the information on the selected object such that the volume of the information on the selected object becomes larger.

(9) The sound control apparatus according to (1) or (2), further including

an image pickup unit configured to pick up an image of a real object that actually exists in space,

in which the controller causes the real object photographed by the image pickup unit to be displayed as the object on the screen and controls a volume of information on the real object based on one of a position and area of the real object on the screen.

(10) The sound control apparatus according to (9),

in which the controller changes, when one of the position and area of the real object photographed by the image pickup unit on the screen is changed, the volume of the information on the real object according to the change of one of the position and area of the real object on the screen.

(11) The sound control apparatus according to (1) or (2),

in which the controller causes a virtual object to be displayed as the object on the screen and controls a volume of information on the virtual object based on one of a position and area of the virtual object on the screen.

(12) The sound control apparatus according to (11),

in which the controller changes one of the position and area of the virtual object on the screen and changes the volume of the information on the virtual object according to the change of one of the position and area of the virtual object on the screen.

(13) The sound control apparatus according to (12), further including

a sensor configured to detect a movement of the sound control apparatus,

in which the controller changes one of the position and area of the virtual object on the screen according to the movement of the sound control apparatus detected by the sensor.

(14) A program that causes a sound control apparatus to execute the steps of:

displaying an object on a screen; and

controlling a volume of information on the object based on one of a position and area of the object on the screen.

(15) A control method, including:

displaying an object on a screen; and

controlling a volume of information on the object based on one of a position and area of the object on the screen.

The present disclosure contains subject matter related to that disclosed in Japanese Priority Patent Application JP 2011-141037 filed in the Japan Patent Office on Jun. 24, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A sound control apparatus, comprising:
a display unit configured to display an object on a screen; and
a controller configured to control a volume of information on the object based on one of a position and area of the object on the screen.

2. The sound control apparatus according to claim 1,
wherein the controller controls a sound signal of a sound output unit such that the information on the object is heard from a direction corresponding to the position of the object on the screen.

3. The sound control apparatus according to claim 1,
wherein the controller controls the volume of the information on the object based on a distance between a center position of the screen and a center position of the object.

4. The sound control apparatus according to claim 3,
wherein the controller controls the volume of the information on the object such that the volume becomes larger as the distance between the center position of the screen and the center position of the object becomes smaller.

5. The sound control apparatus according to claim 1,
wherein the controller controls the volume of the information on the object such that the volume becomes larger as the area of the object on the screen increases.

6. The sound control apparatus according to claim 1,
wherein the controller controls the volume of the information on the object based on both the position and area of the object on the screen.

7. The sound control apparatus according to claim 1, further comprising
an input unit,
wherein the controller judges a selection operation of the object via the input unit and changes the volume of the information on the selected object according to the selection operation of the object.

8. The sound control apparatus according to claim 7,
wherein the controller changes the volume of the information on the selected object such that the volume of the information on the selected object becomes larger.

9. The sound control apparatus according to claim 1, further comprising
an image pickup unit configured to pick up an image of a real object that actually exists in space,
wherein the controller causes the real object photographed by the image pickup unit to be displayed as the object on the screen and controls a volume of information on the real object based on one of a position and area of the real object on the screen.

10. The sound control apparatus according to claim 9,
wherein the controller changes, when one of the position and area of the real object photographed by the image pickup unit on the screen is changed, the volume of the information on the real object according to the change of one of the position and area of the real object on the screen.

11. The sound control apparatus according to claim 1,
wherein the controller causes a virtual object to be displayed as the object on the screen and controls a volume of information on the virtual object based on one of a position and area of the virtual object on the screen.

12. The sound control apparatus according to claim 11,
wherein the controller changes one of the position and area of the virtual object on the screen and changes the volume of the information on the virtual object according to the change of one of the position and area of the virtual object on the screen.

13. The sound control apparatus according to claim 12, further comprising
a sensor configured to detect a movement of the sound control apparatus,
wherein the controller changes one of the position and area of the virtual object on the screen according to the movement of the sound control apparatus detected by the sensor.

14. A program that causes a sound control apparatus to execute the steps of:
displaying an object on a screen; and
controlling a volume of information on the object based on one of a position and area of the object on the screen.

15. A control method, comprising:
displaying an object on a screen; and
controlling a volume of information on the object based on one of a position and area of the object on the screen.
